(19) United States
(12) Patent Application Publication
(10) Pub. No.: US 2025/0028954 A1
(43) Pub. Date: Jan. 23, 2025

(54) METHOD AND COMPUTING DEVICE FOR GENERATING NEURAL NETWORK MODEL AND PERFORMING CIRCUIT SIMULATION BY USING THE NEURAL NETWORK MODEL

(71) Applicant: SAMSUNG ELECTRONICS CO., LTD., Suwon-si (KR)

(72) Inventors: Sanghoon Myung, Suwon-si (KR); Kyeyeop Kim, Suwon-si (KR); Jaehoon Jeong, Suwon-si (KR); Yunji Choi, Suwon-si (KR); Songyi Han, Suwon-si (KR)

(21) Appl. No.: 18/768,183

(22) Filed: Jul. 10, 2024

(30) Foreign Application Priority Data
Jul. 18, 2023 (KR) 10-2023-0093352
Feb. 6, 2024 (KR) 10-2024-0018412

(51) Int. Cl. G06N 3/08

(52) U.S. Cl. CPC G06N 3/08

(57) ABSTRACT

A method of generating a neural network model and performing a circuit simulation by using the neural network model is presented. The method includes generating sample data by performing a process simulation based on a temperature and a process parameter, training the neural network model based on the sample data, performing a lightweight operation on the neural network model to generate a lightweight neural network model, re-training the lightweight neural network model, and performing the circuit simulation with the process parameter as an input by using the re-trained lightweight neural network model.

### CROSS-REFERENCE TO RELATED APPLICATIONS

This application is based on and claims priority under 35 U.S.C. § 119 to Korean Patent Application Nos. 10-2023-0093352, filed on Jul. 18, 2023, and 10-2024-0018412, filed on Feb. 6, 2024, in the Korean Intellectual Property Office, the disclosures of which are incorporated by reference herein in their entireties.

### BACKGROUND

As semiconductors have become highly integrated and miniaturized, factors in each stage of designing and manufacturing semiconductor devices interact in a complex manner, and thus, various unintended electrical characteristics have occurred in semiconductor devices. Accordingly, in order to overcome limitations of semiconductor processes and devices, to understand phenomena, and to reduce experimental costs, demand in the semiconductor industry for a technology computer aided design (TCAD) process-device simulation environment based on a physical simulation has been increasing. In addition, in order to provide accurate product specifications of semiconductor devices, it is necessary to predict and simulate characteristics of semiconductor devices.

### SUMMARY

This disclosure provides a method and computing device for generating a neural network model with improved performance and reduced cost and performing a circuit simulation by using the neural network model.

This disclosure relates to modeling, and more particularly, to a method and computing device for generating a neural network model and performing a circuit simulation by using the neural network model.

Modeling techniques may be used to estimate objects or phenomena having a causal relationship, and models generated through modeling techniques may be used to predict or optimize objects or phenomena.

According to some implementations, there is provided a method of generating a neural network model and performing a circuit simulation by using the neural network model, the method including generating sample data by performing a process simulation based on a temperature and a process parameter, training the neural network model based on the sample data, performing a lightweight operation on the neural network model to generate a lightweight neural network model, re-training the lightweight neural network model, and performing the circuit simulation with a process parameter as an input by using the re-trained lightweight neural network model.

According to some examples, there is provided a computing device including at least one processor and a memory, wherein the memory stores instructions that, when executed by the at least one processor, allow the at least one processor to generate a neural network model and perform a circuit simulation by using the neural network model, and the at least one processor is configured to generate sample data by performing a process simulation based on a temperature and a process parameter, train the neural network model based on the sample data, perform a lightweight operation on the neural network model to generate a lightweight neural network model, re-train the lightweight neural network model, and perform the circuit simulation with a process parameter as an input by using the re-trained lightweight neural network model.

According to some examples, there is provided a method of generating a neural network model and performing a circuit simulation by using the neural network model, the method including generating sample data by performing a process simulation based on a temperature and a process parameter, dividing the sample data into training data and validation data, training the neural network model based on the training data, determining whether a fit between target data and output data of the neural network model is accurate, adjusting a parameter of the neural network model until a threshold fit between the target data and the output data is reached, performing a lightweight operation on the neural network model to generate a lightweight neural network model, re-training the lightweight neural network model based on the validation data, converting the lightweight neural network model into a format corresponding to a circuit simulator, and performing the circuit simulation with a process parameter as an input by using the converted lightweight neural network model.

### BRIEF DESCRIPTION OF THE DRAWINGS

Embodiments will be more clearly understood from the following detailed description taken in conjunction with the accompanying drawings in which:

FIG. 1 is a flowchart illustrating an example of operations of a computing system according to some implementations;

FIG. 2 is a block diagram illustrating an example of a computing system according to some implementations;

FIGS. 3A to 3C are flowcharts illustrating examples of operations of a computing system;

FIG. 4 is a diagram illustrating input data of a neural network model;

FIG. 5 is a diagram illustrating an example of a neural network model according to some implementations;

FIG. 6 is a diagram illustrating an example of a neural network model according to some implementations;

FIG. 7 is a flowchart illustrating operation S130 of FIG. 1 in detail;

FIG. 8 is a flowchart illustrating operation S150 of FIG. 1 in detail;

FIGS. 9A and 9B are diagrams illustrating a lightweight operation;

FIG. 10 is a flowchart illustrating an example of an operating method of a computing system according to some implementations;

FIG. 11 is a block diagram illustrating a computing system including a memory storing a program, according to some implementations;

FIG. 12 is a block diagram illustrating a computing system accessing a storage medium storing a program, according to some implementations;

FIG. 13 is a flowchart illustrating an example of an operating method of a computing system according to some implementations;

FIG. 14 is a flowchart illustrating an example of a method of manufacturing an integrated circuit, according to some implementations;

FIGS. 15A and 15B are graphs illustrating results of applying a method of generating a neural network model and performing a circuit simulation by using the neural network model, according to some implementations;

FIGS. 16A and 16B are graphs illustrating results of applying a method of generating a neural network model and performing a circuit simulation by using the neural network model, according to implementations; and

FIG. 17 is a graph illustrating results of applying a method of generating a neural network model and performing a circuit simulation by using the neural network model, according to implementations.

### DETAILED DESCRIPTION

Hereinafter, embodiments are described in detail and clearly to such an extent that one of ordinary skill in the art may easily implement them.

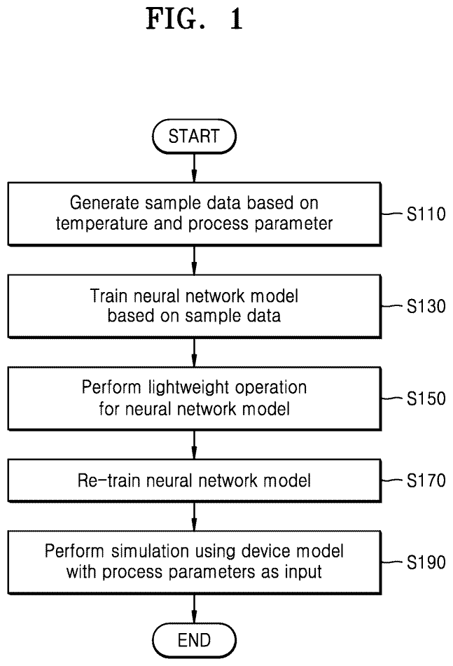

FIG. 1 is a flowchart illustrating an example of operations of a computing system according to some implementations.

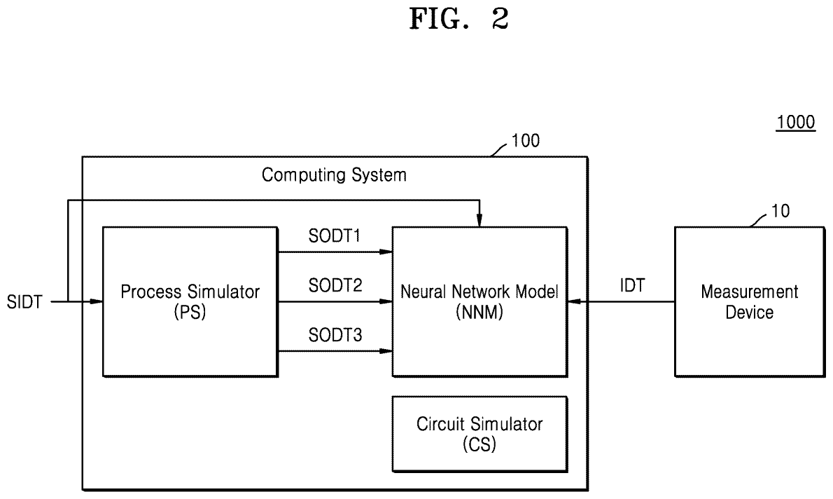

A method of generating a neural network model and performing a circuit simulation by using the neural network model is described with reference to FIG. 1. A computing system 100 (see FIG. 2) may generate a neural network model NNM (see FIG. 2) (or a device model). The neural network model NNM may be a neural network-based device model. The computing system 100 may perform a circuit simulation (e.g., a simulation program with integrated circuit emphasis (SPICE) simulation) by using the neural network model NNM. The method of generating a neural network model and performing a circuit simulation by using the neural network model, according to some implementations, may relate to a method of optimizing a semiconductor process and design.

The computing system 100 may include at least one processor and a non-transitory storage medium storing instructions that, when executed by the at least one processor, allow the at least one processor to generate the neural network model NNM and perform a circuit simulation by using the neural network model NNM.

Hereinafter, various operations performed by the at least one processor of the computing system 100 may be directly implemented by hardware, by software modules executed by the processor, or by a combination thereof. When implemented by software, functions may be stored as one or more instructions or code on a tangible non-transitory storage medium. The software modules may reside on random access memory (RAM), flash memory, read only memory (ROM), electrically programmable ROM (EPROM), electrically erasable programmable ROM (EEPROM), registers, hard disks, removable disks, CD ROM, or any other form of storage medium.

The computing system 100 may perform a simulation while changing input data. The computing system 100 may perform a circuit simulation for an integrated circuit (or a circuit) while changing a process parameter (or a process condition) and a voltage. By using the neural network model NNM, the computing system 100 may generate a simulation result including a current characteristic and a charge characteristic through a circuit simulator CS (see FIG. 2), while changing the process parameter and the voltage.

The neural network model NNM may be implemented in the computing system 100 to model a semiconductor device (or a characteristic of a semiconductor device). For example, the neural network model NNM may model the performance of a transistor or a characteristic of a transistor. The neural network model NNM may receive a voltage and a process parameter to output a current and a charge.

For example, the neural network model NNM may be implemented in a standalone computing system or may be implemented in distributed computing systems that may communicate with each other through a network, etc. In addition, the neural network model NNM may include a portion implemented by a processor executing a program including a series of instructions or may include a portion implemented by logic hardware designed by logic synthesis. Herein, a processor may refer to any hardware-implemented data processing device including a physically structured circuit to execute predefined operations, including operations expressed as instructions and/or code included in a program. For example, the data processing device may include a microprocessor, a central processing unit (CPU), a graphics processing unit (GPU), a neural processing unit (NPU), a processor core, a multi-core processor, a multiprocessor, an application-specific integrated circuit (ASIC), an application-specific instruction-set processor (ASIP), and a field programmable gate array (FPGA).

Referring to FIG. 1, in operation S110, the computing system 100 may generate sample data based on a temperature and a process parameter. In some implementations, computing system 100 may generate the sample data by performing a process simulation (e.g., a technology computer aided design (TCAD) simulation) based on the temperature and the process parameter. The computing system 100 may generate the sample data while changing the temperature and the process parameter. The sample data may include simulator input data SIDT (see FIG. 2) and simulator output data (SODT, SODT1, SODT2, and SODT3) (see FIG. 2). The simulator input data SIDT may be data input to a process simulator PS (see FIG. 2). The simulator output data SODT may be data generated and output by the process simulator PS.

The computing system 100 may generate the simulator output data SODT through the process simulator PS. The computing system 100 may perform a process simulation while changing the simulator input data SIDT to generate the simulator output data SODT. The computing system 100 may perform the process simulation while changing the process parameter in the simulator input data SIDT. The computing system 100 may perform the process simulation while changing the process parameter in consideration of a process variation. The process simulator PS may receive the simulator input data SIDT including the temperature and the process parameter and may output a current-voltage characteristic and a charge-voltage characteristic as the simulator output data SODT.

In some implementations, the computing system 100 may receive sample data from an external source. For example, the sample data may include measurement data IDT (see FIG. 2). The computing system 100 may receive the measurement data IDT from a measurement device 10 (see FIG. 2).

In operation S130, the computing system 100 may train the neural network model NNM based on the sample data. In some implementations, the computing system 100 may train the neural network model NNM based on a difference between target data in the sample data and output data. For example, the target data may refer to an expected value or actual value corresponding to output data of the neural network model NNM in the sample data. For example, the target data may include the simulator output data SODT and the measurement data IDT in the sample data. In some implementations, computing system 100 may train the neural network model NNM based on all weights of the neural network model NNM.

In operation S150, the computing system 100 may perform a lightweight operation for the neural network model NNM. The lightweight operation may refer to an operation of reducing the complexity of the neural network model NNM or may be referred to as a compression of the model. In some implementations, the lightweight operation may refer to an operation of setting some of the weights of the neural network model NNM to ‘0’. For example, the lightweight operation may be a pruning operation.

In some implementations, the computing system 100 may split the weights of the neural network model NNM into a first weight group and a second weight group. The first weight group may include weights to be excluded during a re-training operation. The second weight group may include weights to be used in a re-training operation. The computing system 100 may allocate 50% of all weights to the first weight group and may allocate 50% of all weights to the second weight group. The computing system 100 may initialize the weights included in the first weight group. For example, the computing system 100 may initialize the weights included in the first weight group to ‘0’.

In operation S170, the computing system 100 may re-train the neural network model NNM. The computing system 100 may re-train the lightweight neural network model NNM. In some implementations, the computing system 100 may train the neural network model NNM based only on the weights included in the second weight group. The computing system 100 may train the neural network model NNM based on the weights included in the second weight group, excluding the weights included in the first weight group. The computing system 100 may re-train the neural network model NNM based on 50% of all weights.

In operation S190, the computing system 100 may perform (or run) a circuit simulation by using the neural network model NNM with process parameters for an integrated circuit as an input. The computing system 100 may perform a simulation for an integrated circuit by using the neural network model NNM, while changing a voltage and a process parameter. The computing system 100 may input a process parameter and a voltage to the circuit simulator CS. The computing system 100 may execute the circuit simulator CS. The computing system 100 may generate a characteristic of an integrated circuit as a simulation result. The computing system 100 may generate a current and a charge corresponding to input data.

In optimizing a semiconductor process and design, performing a process simulation takes a long time. In addition, extracting a model parameter based on a process simulation result takes a long time. However, the computing system 100 according to some implementations may generate the neural network model NNM and perform a circuit simulation by using the neural network model NNM. The neural network model NNM may receive a process parameter and a voltage as input data and may output a current and a charge as output data. The computing system 100 may perform semiconductor process-design optimization by performing the method according to some implementations to generate the neural network model NNM and perform circuit simulation by using the neural network model NNM.

As described above, the computing system 100 according to some implementations may perform a circuit simulation by using the neural network model NNM that receives process parameters and voltage as input data and outputs current and charge as output data. That is, by integrating process simulation into circuit simulation, a computation time may be reduced. In addition, a Monte Carlo (MC) simulation may be supported (or provided) by using the neural network model NNM according to some implementations. Accordingly, a turnaround time (TAT) of semiconductor process and design optimization may be reduced.

Hereinafter, for convenience of description, terms such as “neural network model” and “device model” are used interchangeably. These terms may have the same meaning or different meanings depending on the context of embodiments, and the meaning of each term will be understood according to the context of embodiments to be described.

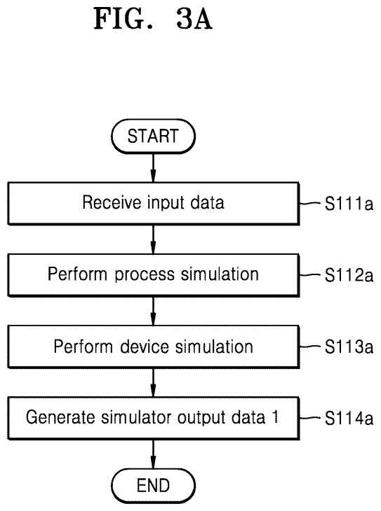

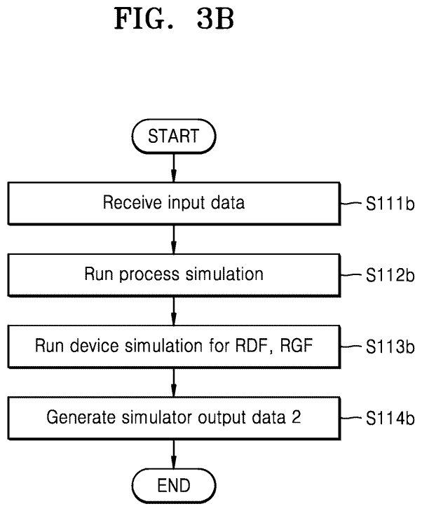

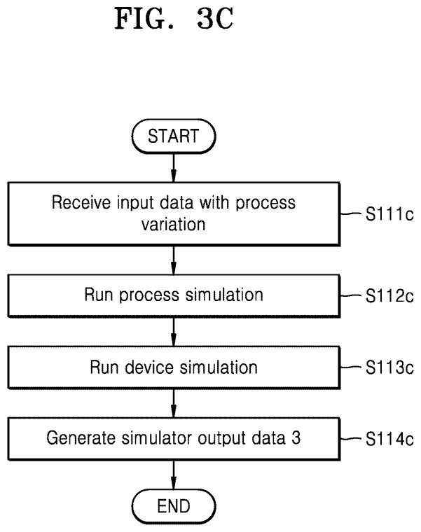

FIG. 2 is a block diagram illustrating an example of a computing system according to some implementations. FIGS. 3A to 3C are flowcharts illustrating examples of operations of a computing system.

A method of generating sample data is described with reference to FIGS. 2 and 3A to 3C. Referring to FIG. 2, a semiconductor system 1000 may include the computing system 100 and the measurement device 10. In some implementations, the computing system 100 may be implemented separately from the measurement device 10. However, the scope of the disclosure is not limited thereto, and the computing system 100 and the measurement device 10 may be implemented as a single semiconductor system 1000.

The computing system 100 may include the process simulator PS, the circuit simulator CS, and the neural network model NNM. The computing system 100 may be referred to as a neural network system. The computing system 100 may generate the neural network model NNM. The computing system 100 may train the neural network model NNM. The computing system 100 may optimize parameters of the neural network model NNM. The computing system 100 may perform a computation of the neural network model NNM based on received input data. The computing system 100 may generate an information signal or may re-train the neural network model NNM, based on a computation result. The computing system 100 may include a hardware accelerator for executing the neural network model NNM. The hardware accelerator may, for example, correspond to an NPU, a tensor processing unit (TPU), a neural engine, etc., which are modules dedicated to executing the neural network model NNM, but is not limited thereto.

The computing system 100 according to some implementations may execute the neural network model NNM. The neural network model NNM refers to a deep learning model that is trained to perform specific operations such as process simulation, model parameter extraction, and device modeling. The neural network model NNM may be a neural network model used by the computing system 100 to extract a desired information signal.

For example, the neural network model NNM may include at least one of various types of neural network models, such as a convolution neural network (CNN), a region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, a long short-term memory (LSTM) network, a classification network, a generative adversarial network (GAN), a transformer, and an attention network.

The neural network model NNM may be generated and trained in the computing system 100, and the neural network model NNM that has been trained may be executed in the computing system 100. Hereinafter, the neural network model NNM refers to a neural network model of which configuration parameters (e.g., network topology, bias, weight, etc.) are determined through training. The configuration parameters of the neural network model NNM may be updated through retraining in the computing system 100, so that the neural network model NNM that has been updated (or the neural network model NNM that has been converted) may be applied to the computing system 100.

In some implementations, the neural network model NNM may be applied to the circuit simulator CS. The circuit simulator CS may include the neural network model NNM that has been converted. The circuit simulator CS may perform circuit simulation by using the neural network model NNM that has been converted.

The measurement device 10 or inspection equipment may measure a characteristic of a semiconductor device and may generate measurement data IDT. The measurement data IDT may be data including an electrical/structural characteristic of a semiconductor product (or a semiconductor device) that has been actually measured. For example, the measurement data IDT of a semiconductor device may be generated through a method of measuring an electrical characteristic by a test element group (TEG). For example, the measurement data IDT of the semiconductor device may be generated by fabricating a TEG on a wafer and measuring an electrical characteristic according to measurement requirements from the wafer with the TEG. The measurement data IDT of the semiconductor device generated by the measurement device 10 may be data corresponding to the simulator output data SODT of the process simulator PS.

The process simulator PS, which is a physical model designed to simulate an actual environment, may perform a simulation based on input data and produce output data as a simulation result. Alternatively, the process simulator PS may analyze and simulate physical phenomena such as electrical, mechanical, and physical characteristics of a semiconductor device. In some implementations, the process simulator PS may be implemented by a mathematical equation based on mathematical and physical theories. For example, the process simulator PS may be a transistor simulation tool. For example, the process simulator PS may be a TCAD simulator and/or an electronic computer aided design (ECAD) simulator.

In some implementations, the process simulator PS may receive the simulator input data SIDT. The simulator input data SIDT may include an input parameter and environmental information required for a simulation. For example, the environmental information may include factors (e.g., a simulation flow, input/output information about each simulator, etc.) other than an input parameter which needs to be set for a simulator to perform a simulation.

In some implementations, the process simulator PS may simulate a characteristic of a process, device, or circuit of a semiconductor device and may output the simulator output data SODT as a simulation result. For example, the process simulator PS may simulate each process step based on material, structure, or process input data. One or more process steps may include an oxidation process, a photoresist coating process, an exposure process, a development process, an etching process, an ion implantation process, a diffusion process, a chemical vapor deposition process, and a metallization process. The process simulator PS may simulate at least one device based on simulation results for process steps and may output device characteristic data (or device data). The process simulator PS may generate and output the simulator output data SODT including information about an electrical/structural characteristic of a semiconductor device.

In some implementations, the simulator input data SIDT of the process simulator PS may include a temperature, a process parameter (or a process condition), etc. The process simulator PS may perform a simulation by using received data. The process simulator PS may output the simulator output data SODT. The process simulator PS may output, as a simulation result, the simulator output data SODT including current-voltage characteristic data, charge-voltage characteristic data, etc. The process simulator PS may transmit the simulator output data SODT to the neural network model NNM.

In some implementations, the neural network model NNM may receive sample data. The sample data may include the simulator input data SIDT, the simulator output data SODT, and the measurement data IDT. The simulator output data SODT may include first simulator output data SODT1, second simulator output data SODT2, and third simulator output data SODT3. The first simulator output data SODT1 may include current-voltage average data and charge-voltage average data. The second simulator output data SODT2 may include current-voltage local variance data and charge-voltage local variance data. The third simulator output data SODT3 may include current-voltage global variance data and charge-voltage global variance data. For example, local variance data may indicate a variation within a wafer. Global variance data may indicate a wafer-to-wafer variation.

The process simulator PS may generate the first simulator output data SODT1. A method of generating the first simulator output data SODT1 is described in detail with reference to FIG. 3A. The process simulator PS may generate the second simulator output data SODT2. A method of generating the second simulator output data SODT2 is described in detail with reference to FIG. 3B. The process simulator PS may generate the third simulator output data SODT3. A method of generating the third simulator output data SODT3 is described in detail with reference to FIG. 3C. The process simulator PS may output the first to third simulator output data SODT1 to SODT3 to the neural network model NNM.

That is, the computing system 100 may generate the first to third simulator output data SODT1 to SODT3 through the process simulator PS. The computing system 100 may generate current-voltage average data, current-voltage local variance data, current-voltage global variance data, charge-voltage average data, charge-voltage local variance data, and charge-voltage global variance data through the process simulator PS.

The circuit simulator CS may be a simulation tool for simulating an integrated circuit. For example, the circuit simulator CS may be an electronic design automation (EDA) tool and/or a SPICE tool. The circuit simulator CS may simulate an integrated circuit by using the neural network model NNM. The circuit simulator CS may simulate a characteristic of each element (e.g., transistors) of an integrated circuit by using the neural network model NNM. For example, simulating an integrated circuit may refer to applying a voltage and/or a current to one node of the integrated circuit and generating a simulation result including a voltage and/or a current for another node of the integrated circuit.

The computing system 100 may perform an integrated circuit simulation to design an integrated circuit. The computing system 100 may execute the circuit simulator CS. The computing system 100 may run the circuit simulator CS that simulates an operation of at least one element of an integrated circuit.

The computing system 100 may perform a circuit simulation by using the neural network model NNM. That is, by mounting the neural network model NNM on the circuit simulator CS, the computing system 100 may perform a circuit simulation. The computing system 100 may run the circuit simulator CS by using the neural network model NNM. Based on a result of simulating an integrated circuit, an operation of manufacturing an integrated circuit by a semiconductor process may be performed.

Referring to FIG. 3A, the computing system 100 may generate the first simulator output data SODT1 including current-voltage average data and charge-voltage average data. In operation S111a, the process simulator PS may receive input data. For example, the input data may include a temperature or a process parameter (or a process requirement). The process parameter may include a technology parameter that varies as a design tool for designing a target semiconductor device changes and a design parameter that varies according to the physical/structural characteristics of the target semiconductor device. For example, when the target semiconductor device is a transistor, the design parameter may include a gate line length, an active area width, a channel length, a device width, a doping profile, an oxide film thickness, an oxide film dielectric constant, a channel length modulation constant, a temperature at which the target semiconductor device is driven, etc.

In operation S112a, the process simulator PS may perform a process simulation. For example, the process simulator PS may perform a TCAD process simulation. In operation S113a, the process simulator PS may perform a device simulation. For example, the process simulator PS may perform a TCAD device simulation.

In operation S114a, the process simulator PS may generate the first simulator output data SODT1. The process simulator PS may generate current-voltage average data and charge-voltage average data.

Referring to FIG. 3B, the computing system 100 may generate the second simulator output data SODT2 including current-voltage local variance data and charge-voltage local variance data. In operation S111b, the process simulator PS may receive input data.

In operation S112b, the process simulator PS may perform a process simulation. For example, the process simulator PS may perform a TCAD process simulation. In operation S113b, the process simulator PS may perform a device simulation. For example, the process simulator PS may perform a TCAD device simulation. The process simulator PS may perform a TCAD device simulation based on a doping profile. The process simulator PS may perform a TCAD device simulation for a random dopant fluctuation (RDF) and a random geometry fluctuation (RGF).

In operation S114b, the process simulator PS may generate the second simulator output data SODT2. The process simulator PS may generate current-voltage local variance data and charge-voltage local variance data.

Referring to FIG. 3C, the computing system 100 may perform a simulation considering a process variation. The computing system 100 may generate the third simulator output data SODT3 including current-voltage global variance data and charge-voltage global variance data. In operation S111c, the process simulator PS may receive input data reflecting a process variation. The input data may be generated considering a process variation.

In operation S112c, the process simulator PS may perform a process simulation. For example, the process simulator PS may perform a TCAD process simulation. In operation S113c, the process simulator PS may perform a device simulation. For example, the process simulator PS may perform a TCAD device simulation.

In operation S114c, the process simulator PS may generate the third simulator output data SODT3. The process simulator PS may generate current-voltage global variance data and charge-voltage global variance data.

As described above, the computing system 100 may generate sample data. The sample data may include the first simulator output data SODT1, the second simulator output data SODT2, and the third simulator output data SODT3. The first simulator output data SODT1 may include current-voltage average data and charge-voltage average data. The second simulator output data SODT2 may include current-voltage local variance data and charge-voltage local variance data. The third simulator output data SODT3 may include current-voltage global variance data and charge-voltage global variance data.

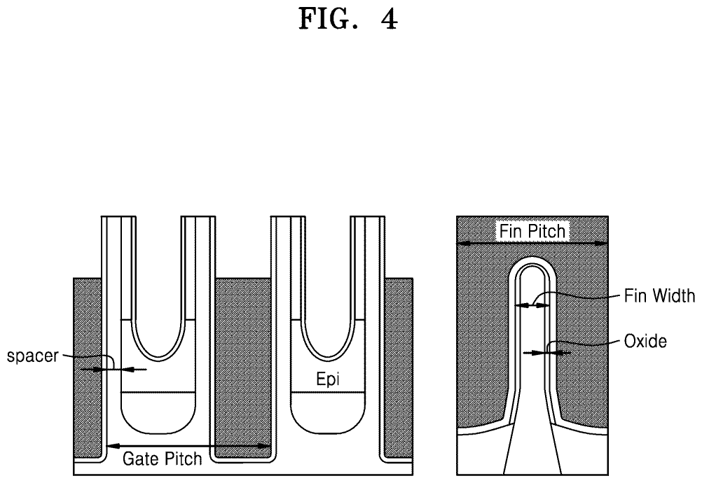

FIG. 4 is a diagram illustrating input data of a neural network model.

The neural network model NNM may receive input data. The input data may include both an input parameter of the process simulator PS and an input parameter of the circuit simulator CS. The input parameter of the circuit simulator CS may include an operating parameter, a temperature, a channel length, a gate length, a field effect transistor (FET) width, the number of pins, etc., according to requirements of an environment in which a target semiconductor device operates. The operating parameter may refer to a voltage input to the target semiconductor device. For example, the operating parameter may include a drain voltage, a gate voltage, a source voltage, and a body voltage. The input parameter of the process simulator PS may include a technology parameter that varies as a design tool for designing a target semiconductor device changes and a design parameter that varies according to the physical/structural characteristics of the target semiconductor device.

TABLE 1

| | |
|---|---|
| Structure | Oxide/Spacer |
| | Thickness |
| | Fin Width |
| | Fin Pitch |
| | Gate Pitch |
| | Epi |
| Doping | Well IIP |
| | S/D IIP |

Table 1 shows examples of design parameters. For example, the design parameters may include structural parameters and doping parameters. As shown in FIG. 4, the structural parameters may include an oxide/spacer, a thickness, a fin width, a fin pitch, a gate pitch, an Epi (Epitaxial), etc. The doping parameters may include a well ion implantation (IIP), a source/drain (S/D) IIP, etc. In one embodiment, input data of the neural network model NNM may include a voltage and a process parameter. The voltage may refer to an operating parameter. The process parameter may include a technology parameter and a design parameter.

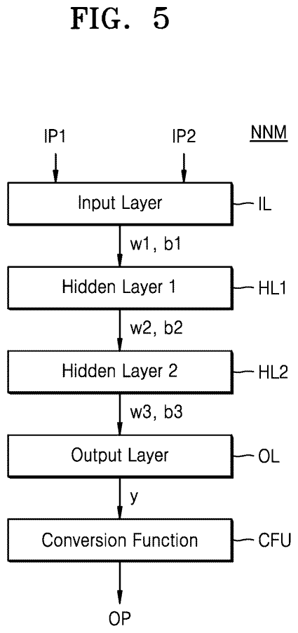

FIG. 5 is a diagram illustrating an example of a neural network model according to some implementations.

Referring to FIG. 5, the neural network model NNM may include an input layer IL, one or more hidden layers (e.g., a first hidden layer HL1 and a second hidden layer HL2), an output layer OL, and a conversion function unit CFU. Although the neural network model NNM of FIG. 5 includes two hidden layers HL1 and HL2, the scope of the disclosure is not limited thereto. The number of hidden layers HL1 and HL2 included in the neural network model NNM may increase or decrease depending on implementation.

The neural network model NNM may receive input data and may generate and output output data. The input data may include an operating parameter, a technology parameter, a design parameter, a channel length, a gate length, an FET width, a temperature, the number of pins, etc. The input data may include a voltage and a process parameter. The voltage may refer to an operating parameter, and the process parameter may refer to a technology parameter and a design parameter. The output data may include a current and a charge.

In some implementations, the input data may include a first input parameter IP1 and a second input parameter IP2. The first input parameter IP1 may refer to an input parameter of the circuit simulator CS. The second input parameter IP2 may refer to an input parameter of the process simulator PS.

The input layer IL may receive the input data. The input layer IL may receive the first input parameter IP1 and the second input parameter IP2. The input layer IL may include the voltage and the process parameter. The input layer IL may apply a weight and a bias to the received input data and may output the input data to the first hidden layer HL1. The input layer IL may be connected to the first hidden layer HL1.

In some implementations, outputs of each layer may be mapped to inputs of a next layer in a fully complete manner, based on an affine transformation in the form of Wx+b. For example, input parameters for the input layer IL may be mapped to the first hidden layer HL1 by a first weight W1 and first biases bL. Outputs of the first hidden layer HL1 may be mapped to inputs of the second hidden layer HL2 by a second weight W2 and second biases b2. Outputs of the second hidden layer HL2 may be mapped to the output layer OL by a third weight W3 and third biases b3.

In some implementations, the hidden layers HL1 and HL2 may receive an output of a previous layer. Each node included in the hidden layers HL1 and HL2 may apply different weights and different biases to the sum of values received from the previous layer and may output the sum of the values to a next layer. The hidden layers HL1 and HL2 may be connected to the previous layer. The hidden layers HL1 and HL2 may be connected to the next layer. For example, the first hidden layer HL1 may be connected to the input layer IL. The first hidden layer HL1 may be connected to the second hidden layer HL2. The second hidden layer HL2 may be connected to the output layer OL.

In some implementations, an activation function may be located between an output of an affine transformation and an input of a next layer. For example, the activation function may include a rectified linear (ReLU) function, a sigmoid function, etc. However, the scope of the disclosure is not limited thereto.

In some implementations, the output layer OL may be connected to the hidden layers HL1 and HL2. For example, the output layer OL may be connected to the second hidden layer HL2. The output layer OL may receive an output of the second hidden layer HL2. The output layer OL may calculate an output value y by adding up all received values. The output layer OL may output the output value y to the conversion function unit CFU. The conversion function unit CFU may convert the output value y into an output parameter OP corresponding to a current and a charge.

To prevent computational errors during training of the neural network model NNM, a preprocessing operation may be performed by using an inverse hyperbolic sine function. When a voltage between a source and a drain is ‘0’, a current between the source and drain may be ‘0’. For this, a current I may be defined by Equation 1. The current I may refer to a current between a source and a drain. Here, I₀ may indicate a normalization factor, V may indicate a voltage between a source and a drain, and y may indicate an output value. A charge Q may be defined by Equation 2. Here, Q₀ may indicate a normalization factor, and y may indicate an output value.

$$I = {I}_{0} \cdot V \cdot sinh y \qquad [ Equation 1 ]$$

$$Q = {Q}_{0} \cdot y \qquad [ Equation 2 ]$$

As described above, the neural network model NNM may receive a voltage and a process parameter as input data and may output a current and a charge as output data. The computing system 100 may generate and train the neural network model NNM. The computing system 100 may generate the neural network model NNM (or a device model) capable of accurately predicting a characteristic of a semiconductor device.

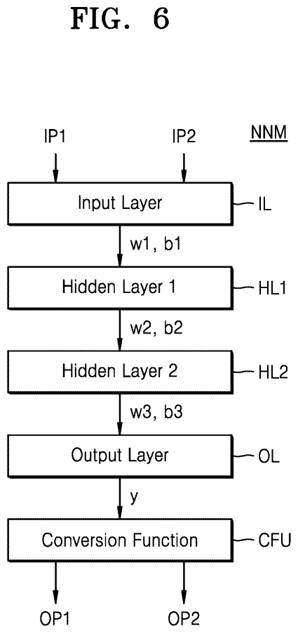

FIG. 6 is a diagram illustrating an example of a neural network model according to some implementations.

For convenience of description, detailed description of the components described above is omitted. Referring to FIG. 6, the neural network model NNM may include the input layer IL, one or more hidden layers, the output layer OL, and the conversion function unit CFU. The neural network model NNM may receive input data and may generate output data. In some implementations, the input data may include the first input parameter IP1 and the second input parameter IP2.

In some implementations, the output data may include a first output parameter OP1 and a second output parameter OP2. The first output parameter OP1 may include average data and local variance data. The first output parameter OP1 may include current average data, current local variance data, charge average data, and charge local variance data. The second output parameter OP2 may include average data and global variance data. The second output parameter OP2 may include current average data, current global variance data, charge average data, and charge global variance data.

As described above, the neural network model NNM may receive a voltage and a process parameter as input data and may output the first output parameter OP1 and the second output parameter OP2 as output data. That is, the neural network model NNM may output average data, local variance data, and global variance data. Accordingly, the neural network model NNM may support (or provide) an MC simulation.

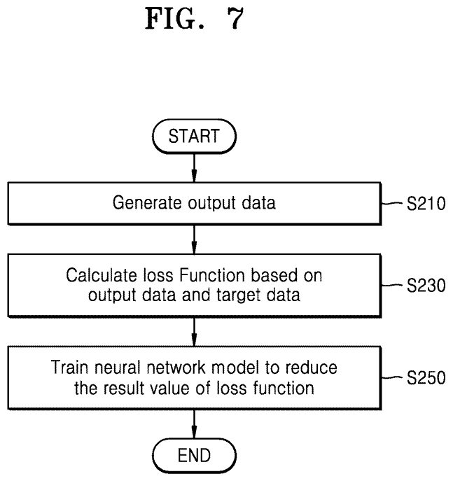

FIG. 7 is a flowchart illustrating operation S130 of FIG. 1 in detail.

Referring to FIGS. 1 and 7, the computing system 100 may generate output data by using the neural network model NNM. The computing system 100 may perform a training operation for the neural network model NNM based on output data and target data of the neural network model NNM. The computing system 100 may train the neural network model NNM based on errors of the output data and the target data. For example, the target data may be the simulator output data SODT in the sample data. Alternatively, the target data may be the measurement data IDT.

For example, the computing system 100 may repeatedly perform an operation of correcting a weight of the neural network model NNM to reduce an error between the output data and the target data. In some implementations, the computing system 100 may train the neural network model NNM in various ways. For example, the computing system 100 may perform automatic parameter optimization (backward propagation) through machine learning.

Operation S130 of FIG. 1 may include operations S210 to S250. In operation S210, the neural network model NNM may generate output data. The neural network model NNM may generate output data including the first output parameter OP1 and the second output parameter OP2.

In operation S230, the computing system 100 may calculate a loss function based on the output data and target data. The loss function may be defined to evaluate the output data of the neural network model NNM. For example, the loss function may be referred to as a cost function. The loss function may be defined such that as the output data moves away from an expected value (or a measured value) (e.g., simulator output data in the sample data or measurement data in the sample data), a result value of the loss function increases. The result value of the loss function may increase as a difference between the output data and the target data increases.

In operation S250, the computing system 100 may train the neural network model NNM to reduce the result value of the loss function. The computing system 100 may correct weights of the neural network model NNM based on values backward propagated from the result value of the calculated loss function. The computing system 100 may correct the weights of the neural network model NNM to reduce the result value of the loss function.

In some implementations, a Kullback-Leibler divergence (KL(p,q) or D_{KL}) may be used as the loss function. A global variance and a local variance follow independent normal distributions with the same mean and different standard deviations. The loss function may be defined by Equation 3. D_{KL} may be defined by Equation 4. N may indicate a normal distribution, μ_{P}_{_{G}} may indicate average data in the second output parameter OP2, σ_{P}_{_{G}}² may indicate global variance data in the second output parameter OP2, μ_{T}_{_{G}} may indicate average data in the target data, σ_{T}_{_{G}}² my indicate global variance data in the target data, μ_{P}_{_{L}} may indicate average data in the first output parameter OP1, σ_{P}_{_{L}}² may indicate local variance data in the first output parameter OP1, μ_{T}_{_{L}} may indicate average data in the target data, and σ_{T}_{_{L}}² may indicate local variance data in the target data.

$$Loss = {D}_{KL} ( 𝒩 ( {μ}_{{P}_{G}} , {σ}_{{P}_{G}}^{2} ) , 𝒩 ( {μ}_{{T}_{G}} , {σ}_{{T}_{G}}^{2} ) ) + {D}_{KL} ( 𝒩 ( {μ}_{{P}_{L}} , {σ}_{{P}_{L}}^{2} ) , 𝒩 ( {μ}_{{T}_{L}} , {σ}_{{T}_{L}}^{2} ) ) \qquad [ Equation 3 ]$$

$$∴ KL ( p , q ) = - \int p ( x ) log q ( x ) dx + \int p ( x ) log p ( x ) dx = \frac{1}{2} log ( 2 {πσ}_{2}^{2} ) + \frac{{σ}_{1}^{2} + {( {μ}_{1} - {μ}_{2} )}^{2}}{2 {σ}_{2}^{2}} - \frac{1}{2} ( 1 + log ( 2 {πσ}_{1}^{2} ) ) = log \frac{{σ}_{2}}{{σ}_{1}} + \frac{{σ}_{1}^{2} + {( {μ}_{1} - {μ}_{2} )}^{2} )}{2 {σ}_{2}^{2}} - \frac{1}{2} \qquad [ Equation 4 ]$$

As described above, the neural network model NNM according to some implementations may generate output data including the first output parameter OP1 and the second output parameter OP2. The neural network model NNM may calculate a loss function based on the output data and target data. The computing system 100 may train the neural network model NNM to reduce a resulting value of the loss function. Accordingly, the consistency of the neural network model NNM may be improved, and the accuracy of a simulation result for a characteristic of an integrated circuit may be improved.

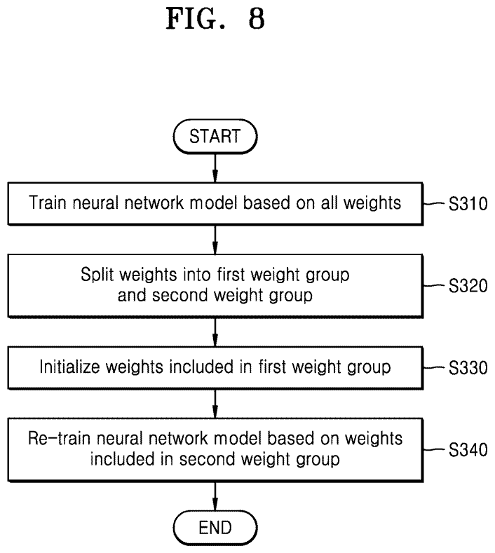

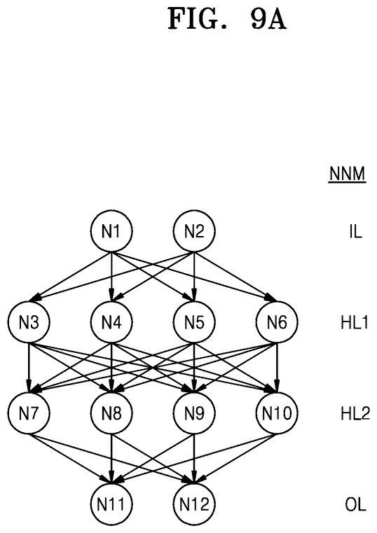

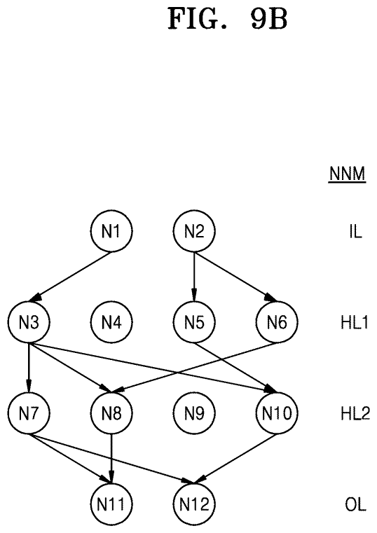

FIG. 8 is a flowchart illustrating operation S150 of FIG. 1 in detail. FIGS. 9A and 9B are diagrams illustrating a lightweight operation.

Referring to FIGS. 1, 8, 9A, and 9B, the computing system 100 may perform a lightweight operation for the neural network model NNM. The computing system 100 may perform a lightweight operation to reduce the complexity of the neural network model NNM. The computing system 100 may perform a lightweight operation capable of reducing the complexity of the neural network model NNM, while maintaining the consistency of the neural network model NNM. Operation S130 of FIG. 1 may correspond to operation S310. Operation S150 of FIG. 1 may include operations S320 and S330. Operation S170 of FIG. 1 may correspond to operation S340.

As described with reference to FIGS. 4 and 5, the neural network model NNM may include the input layer IL, the first hidden layer HL1, the second hidden layer HL2, and the output layer OL. Each of the layers may include a plurality of nodes referred to as neurons. Each node or neuron may indicate a calculation unit having one or more inputs and outputs. Each input from a plurality of nodes of a layer may be supplied from each node of an adjacent layer. Similarly, outputs of a plurality of nodes of a layer may be supplied to a plurality of nodes of an adjacent layer. Each node of a specific layer of the neural network model NNM may be connected to at least some nodes of an adjacent layer.

For example, the input layer IL may include a first node N1 and a second node N2. The first hidden layer HL1 may include a third node N3, a fourth node N4, a fifth node N5, and a sixth node N6. The second hidden layer HL2 may include a seventh node N7, an eighth node N8, a ninth node N9, and a tenth node N10. The output layer OL may include an eleventh node N11 and a twelfth node N12.

In operation S310, the computing system 100 may train the neural network model NNM based on all weights. Referring to FIG. 9A, all nodes, that is, the first to twelfth nodes N1 to N12, of the neural network model NNM may be fully-connected to each other. For example, the first node N1 may transmit a first output to the third node N3, may transmit a second output to the fourth node N4, may transmit a third output to the fifth node N5, and may transmit a fourth output to the sixth node N6. Connection relationships between the remaining nodes, that is, the second to twelfth nodes N2 to N12, are similar thereto, and thus, detailed description thereof is omitted.

In operation S320, the computing system 100 may split the weights into a first weight group and a first weight group. The first weight group may include weights to be initialized. The second weight group may include weights to be used for re-training. The first weight group may include half of all weights (i.e., 50% of all weights). The second weight group may include half of all weights (i.e., 50% of all weights).

In some implementations, the computing system 100 may split the weights into the first weight group and the second weight group, considering the degree of relevance to output parameters and the degree of influence on inferring the output parameters. The computing system 100 may classify weights of low importance into the first weight group and may classify weights of high importance into the second weight group.

For example, the computing system 100 may sort values of the weights in an ascending order or a descending order. The computing system 100 may split the weights into the first weight group and the second weight group based on the size of the sorted data. For example, the computing system 100 may classify weights in lower 50% in size of the weights into the first weight group and may classify the remaining weights into the second weight group. Criteria for splitting the weights into two groups are not limited thereto, and the weights of low importance may be extracted through various methods. That is, the computing system 100 may select weights to be excluded when performing re-training.

In operation S330, the computing system 100 may initialize the weights included in the first weight group. For example, the computing system 100 may set the weights included in the first weight group to ‘0’.

In operation S340, the computing system 100 may re-train the neural network model NNM based on the weights included in the second weight group. To reduce the complexity of the neural network model NNM, the computing system 100 may perform re-training based only on the weights included in the second weight group, excluding the weights included in the first weight group.

Referring to FIG. 9B, because the computing system 100 has initialized the weights included in the first weight group, each of the nodes of the neural network model NNM may be connected to some nodes of an adjacent layer. For example, the first node N1 may transmit an output to the third node N3. The first node N1 may not transmit an output to the fourth node N4, the fifth node N5, and the sixth node N6. The second node N2 may transmit an output only to the fifth node N5 and the sixth node N6. The third node N3 may transmit an output only to the seventh node N7, the eighth node N8, and the tenth node N10. The fifth node N5 may transmit an output only to the tenth node N10. The sixth node N6 may transmit an output only to the eighth node N8. The seventh node N7 may transmit an output to the eleventh node N11 and the twelfth node N12. The eighth node N8 may transmit an output only to the eleventh node N11. The tenth node N10 may transmit an output only to the twelfth node N12.

As described above, the computing system 100 may perform a lightweight operation for the neural network model NNM. The computing system 100 may train the neural network model NNM based on all weights. The computing system 100 may split the weights into a first weight group and a second weight group. The computing system 100 may initialize the weights of the first weight group. The computing system 100 may re-train the neural network model NNM based on the weights included in the second weight group. The number of weights included in the first weight group may be half of the number of all weights.

Accordingly, the computing system 100 may reduce the size of the neural network model NNM through a lightweight operation. The computing system 100 may reduce the complexity of the neural network model NNM through the lightweight operation. The computing system 100 may reduce an inference time through the lightweight operation. That is, the computing system 100 may reduce the complexity of the neural network model NNM while maintaining the consistency of the neural network model NNM.

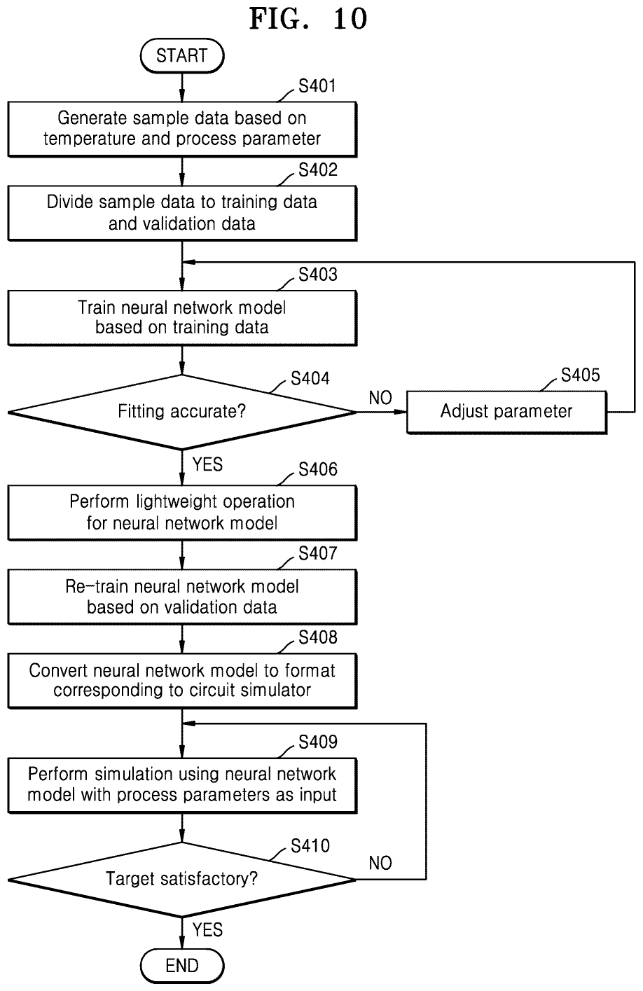

FIG. 10 is a flowchart illustrating an example of an operating method of a computing system according to some implementations.

Referring to FIGS. 1 and 10, by using the neural network model NNM, the computing system 100 may perform a circuit simulation while changing both a process parameter and a voltage. The computing system 100 may perform operations S401 to S410. Operations S401, S403, S406, S407, and S409 are the same as or similar to operations S110 to S190 of FIG. 1, and thus, detailed description thereof is omitted.

In operation S401, the computing system 100 may generate sample data based on a temperature and a process parameter. In operation S402, the computing system 100 may divide the sample data into training data and validation data. The training data may refer to data used in training the neural network model NNM. The validation data may refer to data used in training the lightweight neural network model NNM. That is, the validation data may refer to data used in re-training after a lightweight operation.

In operation S403, the computing system 100 may train the neural network model NNM based on the training data. The computing system 100 may train the neural network model NNM for all weights, based on the training data.

In operation S404, the computing system 100 may determine whether a fit between target data and output data is accurate. The target data may refer to a portion of the sample data. The output data may refer to output data of the neural network model NNM. When the fit is accurate, the computing system 100 may perform operation S406, and when the fit is not accurate, the computing system 100 may perform operation S405.

In operation S405, the computing system 100 may adjust a parameter. In some implementations, the computing system 100 may adjust a parameter (or a hyper-parameter, a weight, a bias, etc.). For example, the computing system 100 may increase or decrease the number of hidden layers. The computing system 100 may increase or decrease the number of nodes of a layer. After adjusting the parameter, the computing system 100 may perform operation S403. The computing system 100 may adjust the parameter and train the neural network model NNM.

In operation S406, the computing system 100 may perform a lightweight operation for the neural network model NNM. The computing system 100 may initialize 50% of all weights to ‘0’. In operation S407, the computing system 100 may re-train the neural network model NNM based on the validation data. The computing system 100 may train the lightweight neural network model NNM, based on the validation data that is different from the training data. The computing system 100 may re-train the neural network model NNM based on 50% of all weights.

In operation S408, the computing system 100 may convert the neural network model NNM into a format corresponding to the circuit simulator CS. The computing system 100 may perform an operation of programming the neural network model NNM to correspond to the circuit simulator CS. For example, the computing system 100 may program the neural network model NNM into a device model by using a model application program interface (API) provided by commercial EDA software, thereby enabling EDA circuit analysis. The device model may be included in a technology design kit used in an EDA tool (e.g., a SPICE tool).

In some implementations, the computing system 100 may port the lightweight neural network model NNM to circuit simulation code, such as a Verilog-A hardware description language (HDL) or a common model interface (CMI) used with a Cadence® Specter® simulator. That is, the computing system 100 may convert the lightweight neural network model NNM into Verilog-A. The computing system 100 may provide the neural network model NNM that has been converted as a device model to the circuit simulator CS. That is, the computing system 100 may generate a device model. For example, the device model may refer to a model converted into a format mountable on the circuit simulator CS.

In operation S409, the computing system 100 may perform a simulation for an integrated circuit by using the neural network model NNM with process parameters as an input. The computing system 100 may perform a circuit simulation for an integrated circuit by using the device model, while changing a process parameter. The computing system 100 may execute the circuit simulator CS by using the device model. For example, computing system 100 may run the circuit simulator CS (e.g., a SPICE simulation tool) that uses the device model.

In some implementations, the device model may be included in the circuit simulator CS. The computing system 100 may execute the circuit simulator CS including the device model to perform a circuit simulation for an integrated circuit. The device model included in the circuit simulator CS may receive a voltage and a process parameter as input data. The device model may infer a current and a charge based on a weight and a parameter and may output the current and the charge to the circuit simulator CS.

In operation S410, the computing system 100 may determine whether characteristics of the circuit satisfy target requirements. The computing system 100 may determine whether characteristics of the circuit resulting from the circuit simulation satisfy requirements. When the characteristics of the circuit do not satisfy the requirements, the computing system 100 may perform operation S409. In some implementations, when the characteristics of the circuit satisfy the requirements, the computing system 100 may perform an operation of manufacturing an integrated circuit by a semiconductor process.

In some implementations, when the characteristics of the circuit do not satisfy the requirements, the computing system 100 may perform a simulation for an integrated circuit while changing a voltage and a process parameter. The computing system 100 may perform a circuit simulation while adjusting a process parameter until the characteristics of the circuit satisfy the requirements. The neural network model NNM may receive a process parameter as an input parameter and may infer a current characteristic and a charge characteristic. Accordingly, the computing system 100 may separately execute the process simulator PS to change a process parameter and generate an electrical characteristic of a semiconductor device and may not perform an operation of extracting a model parameter from the electrical characteristic of the semiconductor device. The computing system 100 may reduce a process development time.

As described herein, according to various implementations, the method of generating a neural network model and performing a circuit simulation by using the neural network model may include performing an MC simulation. The method may use a process parameter as an input. That is, the method may perform a circuit simulation by using a neural network model, while changing a process parameter. The method may reduce a training time of a neural network model. The method may prevent a neural network model from being repeatedly trained according to a process parameter change. The method may perform semiconductor process and design optimization by performing only a circuit simulation. That is, the method may improve a semiconductor process and design optimization by using only a neural network model, without performing a separate process simulation and performing a model parameter extraction based on a process simulation result.

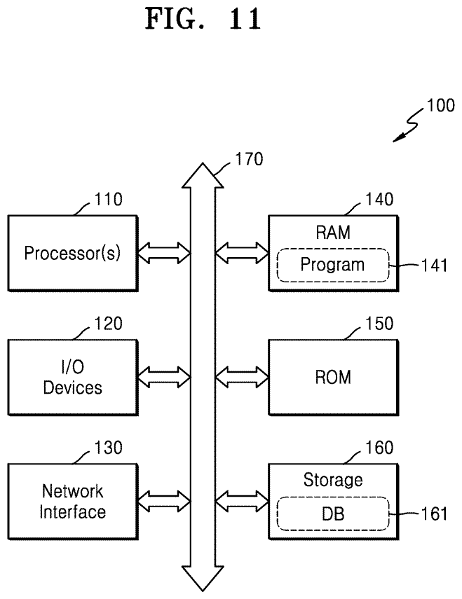

FIG. 11 is a block diagram illustrating a computing system including a memory storing a program, according to some implementations.

At least some of the operations included in the method of generating a neural network model and performing a circuit simulation by using the neural network model may be performed in the computing system 100. In some embodiments, the computing system 100 may be referred to as a neural network system.

The computing system 100 may be a fixed computing system, such as a desktop computer, a workstation, or a server, or may be a portable computing system, such as a laptop computer. As shown in FIG. 11, the computing system 100 may include a processor 110, input/output (I/O) devices 120, a network interface 130, RAM 140, ROM 150, and a storage device 160. The processor 110, the I/O devices 120, the network interface 130, the RAM 140, the ROM 150, and the storage device 160 may be connected to a bus 170 and may communicate with each other through the bus 170.

The processor 110 may be referred to as a processing unit and may include at least one core, such as a microprocessor, an application processor (AP), a digital signal processor (DSP), and a GPU, capable of executing an arbitrary instruction set (e.g., Intel Architecture-32 (IA-32), 64-bit extended IA-32, x86-64, PowerPC, Sparc, million instructions per second (MIPS), advanced reduced instruction set computer (RISC) machine (ARM), IA-64, etc.). For example, the processor 110 may access a memory, that is, the RAM 140 or the ROM 150, through the bus 170 and may execute instructions stored in the RAM 140 or the ROM 150.

The RAM 140 may store a program 141 or at least a portion thereof for performing the method of generating a neural network model and performing a circuit simulation by using the neural network model, and the program 141 may allow the processor 110 to perform at least some of the operations included in the method of generating a neural network model and performing a circuit simulation by using the neural network model. That is, the program 141 may include a plurality of instructions executable by the processor 110, and the plurality of instructions included in the program 141 may allow the processor 110 to perform at least some of the operations included in the above-described method. The program 141 may include the process simulator PS, the circuit simulator CS, and the neural network model NNM.

The storage device 160 may not lose stored data even when power supplied to the computing system 100 is cut off. For example, the storage device 160 may include a non-volatile memory device or may include a storage medium, such as a magnetic tape, an optical disk, or a magnetic disk. In addition, the storage device 160 may be detachable from the computing system 100. The storage device 160 may store the program 141 according to some implementations, and the program 141 or at least a portion thereof may be loaded from the storage device 160 to the RAM 140 before the program 141 is executed by the processor 110.

Alternatively, the storage device 160 may store a file written in a program language, and the program 141 or at least a portion thereof, generated from the file by a compiler, etc., may be loaded to the RAM 140. In addition, as shown in FIG. 11, the storage device 160 may store a database (DB) 161, and the DB 161 may include information, such as sample data, required to perform the method of generating a neural network model and performing a circuit simulation by using the neural network model.

The storage device 160 may store data to be processed by the processor 110 or data processed by the processor 110. That is, the processor 110 may generate data by processing data stored in the storage device 160 and may store the generated data in the storage device 160, according to the program 141.

The I/O devices 120 may include an input device, such as a keyboard or a pointing device, and may include an output device, such as a display device or a printer. For example, a user may trigger execution of the program 141 by the processor 110, may input learning data, and may check result data, through the I/O devices 120.

The network interface 130 may provide access to a network outside the computing system 100. For example, the network may include a plurality of computing systems and a plurality of communication links, and the communication links may include wired links, optical links, wireless links, or any other type of links.

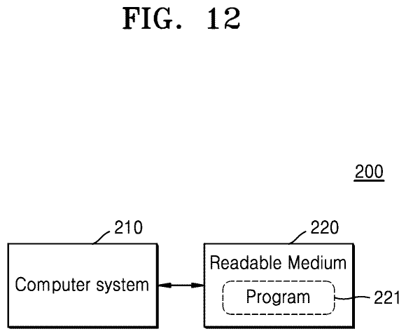

FIG. 12 is a block diagram illustrating a computing system accessing a storage medium storing a program, according to some implementations.

At least some of the operations included in the method of generating a neural network model and performing a circuit simulation by using the neural network model may be performed by a computing system 200. The computing system 200 may include a computer system 210 and a readable medium 220. The computing system 200 may be the computing system 100 described with reference to FIGS. 1 to 11.

The computer system 210 may access the readable medium 220 and may execute a program 221 stored on the readable medium 220. In some embodiments, the computing system 200 may be collectively referred to as a neural network system.

The computer system 210 may include at least one computer subsystem, and the program 221 may include at least one component executed by the at least one computer subsystem. For example, the at least one component may include the neural network model NNM, the process simulator PS, and the circuit simulator CS described above with reference to the drawings. Like the storage device 160 of FIG. 11, the readable medium 220 may include a non-volatile memory device or may include a storage medium, such as a magnetic tape, an optical disk, or a magnetic disk. In addition, the readable medium 220 may be detachable from the computer system 210.

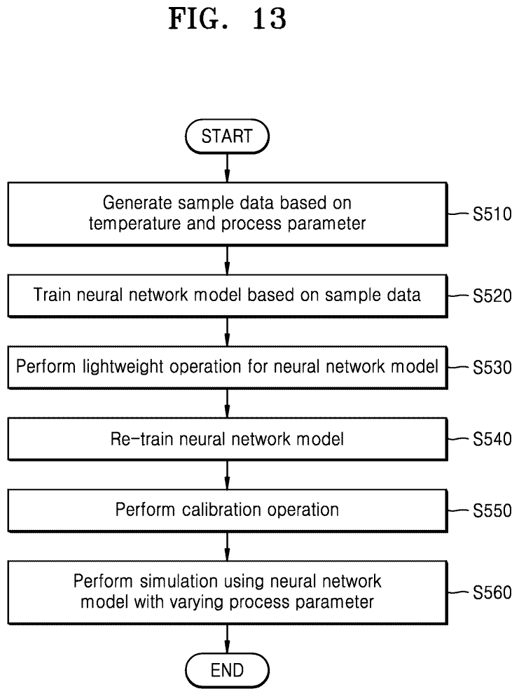

FIG. 13 is a flowchart illustrating an example of an operating method of a computing system according to some implementations.

Referring to FIGS. 1 and 13, the computing system 100 may generate a neural network model and may perform a circuit simulation by using the neural network model. The computing system 100 may perform operations S510 to S560. Operations S510, S520, S530, S540, and S560 are the same as or similar to operations S110, S130, S150, S170, and S190 of FIG. 1, and thus, detailed description thereof is omitted.

In some implementations, even when input data input to the neural network model NNM and input data input to the measurement device 10 are the same, output data generated through the neural network model NNM may be different from the measurement data IDT generated by the measurement device 10. The computing system 100 may perform a calibration operation so that measurement data and output data of the neural network model NNM match each other to within a threshold value. The computing system 100 may correct a difference between the output data of the neural network model NNM and the measurement data through updating the weights or the parameters of the neural network model NNM.

In operation S510, the computing system 100 may generate sample data based on a temperature and a process parameter. In some implementations, the computing system 100 may generate the simulator output data SODT in the sample data through the process simulator PS.

The computing system 100 may sense or receive measurement data for a semiconductor device from the external measurement device 10. For example, the measurement device 10 or inspection equipment may measure a characteristic of a semiconductor device and may generate the measurement data IDT. The measurement data IDT of the semiconductor device generated by the measurement device 10 may be data corresponding to output data of the process simulator PS.

In operation S520, the computing system 100 may train the neural network model NNM based on the sample data. In operation S530, the computing system 100 may perform a lightweight operation for the neural network model NNM. In operation S540, the computing system 100 may re-train the neural network model NNM.

In some implementations, in operation S550, the computing system 100 may perform a calibration operation. The computing system 100 may calibrate the output data of the neural network model NNM to be closer to the measurement data. The computing system 100 may train a transfer learning model based on the measurement data. The computing system 100 may update a difference between the transfer learning model, which has been trained on the measurement data, and the neural network model NNM, which has been trained on simulation data, thereby correcting a difference between the output data and the measurement data in real time.

In operation S560, the computing system 100 may perform a simulation for an integrated circuit by using the neural network model NNM, while changing a process parameter.

As described above, the computing system 100 may perform a calibration operation based on the output data of the neural network model NNM and the measurement data in the sample data. Accordingly, the accuracy of the neural network model NNM may be improved.

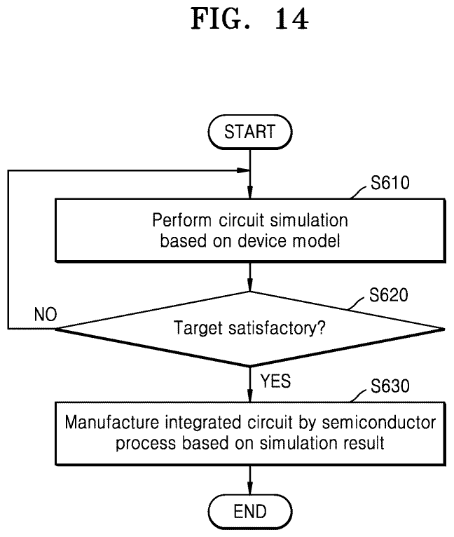

FIG. 14 is a flowchart illustrating an example of a method of manufacturing an integrated circuit, according to some implementations.

Referring to FIG. 14, in operation S610, the computing system 100 may perform a circuit simulation based on a device model. The device model may refer to the lightweight neural network model NNM, and converted, as described above. That is, the device model may refer to the neural network model NNM generated by the method described with reference to FIGS. 1 to 13. The computing system 100 may perform a circuit simulation for an integrated circuit by using the device model. The computing system 100 may perform the circuit simulation and may generate a simulation result. For example, the computing system 100 may input a voltage and a process parameter received from the outside to the circuit simulator CS. The circuit simulator CS may generate a simulation result for the integrated circuit by using the device model.

In operation S620, the computing system 100 may determine whether characteristics of the integrated circuit satisfy target requirements. The computing system 100 may determine whether characteristics of the circuit resulting from the simulation satisfy the requirements. When the characteristics of the circuit do not satisfy the requirements, the computing system 100 may perform operation S610. In some implementations, when the characteristics of the circuit do not satisfy the requirements, the computing system 100 may perform a circuit simulation for a changed integrated circuit by using the device model.

In some implementations, when a process parameter is changed, the computing system 100 may input the changed process parameter to the circuit simulator CS. The computing system 100 may generate a simulation result through the circuit simulator CS using the device model. The computing system 100 may not perform a process simulation for the changed process parameter. In addition, the computing system 100 may not extract a model parameter based on a process simulation result. The computing system 100 may reduce a processing time by not performing a process simulation and not extracting a model parameter.

In some implementations, when the characteristics of the circuit satisfy the requirements, the computing system 100 may perform operation S630. In operation S630, based on the simulation result, an operation of manufacturing an integrated circuit including a target semiconductor device may be performed by a semiconductor process. For example, an integrated circuit may be manufactured through a semiconductor process to which process parameters finally adjusted in operation S610 are applied. The semiconductor process may include a front-end-of-line (FEOL) process and a back-end-of-line (BEOL) process using masks manufactured based on an integrated circuit. For example, the FEOL process may include planarizing and cleaning a wafer, forming a trench, forming a well, forming a gate electrode, forming a source and a drain, etc. In addition, the BEOL process may include siliciding a gate, a source, and drain regions, adding a dielectric, planarizing, forming a hole, adding a metal layer, forming a via, forming a passivation layer, etc.

The integrated circuit manufactured in operation S630 may have a characteristic similar to the simulation result generated in operation S610, due to the high consistency of the neural network model NNM. Accordingly, the time and cost for manufacturing an integrated circuit with good characteristics may be reduced, and an integrated circuit with better characteristics can be manufactured.

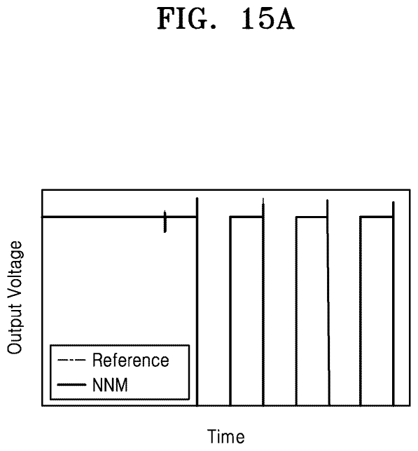

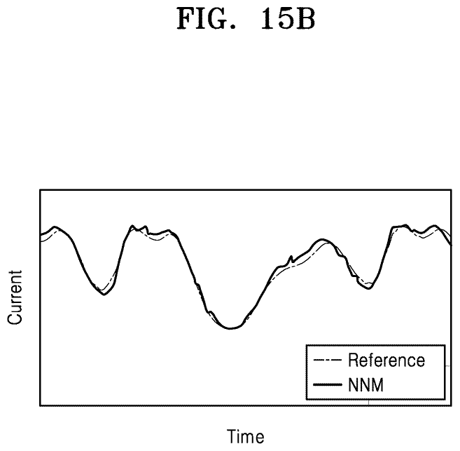

FIGS. 15A and 15B are graphs illustrating results of applying a method of generating a neural network model and performing a circuit simulation by using the neural network model, according to some implementations.

Referring to FIGS. 15A and 15B, results of performing a ring oscillator simulation are shown. A horizontal axis in the graph of FIG. 15A indicates time, and a vertical axis indicates output voltage. A horizontal axis in the graph of FIG. 15B indicates time, and a vertical axis indicates current. In the graphs of FIGS. 15A and 15B, the simulated result is shown in a solid line, and a reference is shown in a dash-single dotted line.

The computing system 100 may perform a circuit simulation by using the neural network model NNM according to some implementations. As a result of the computing system 100 performing a ring oscillator simulation by using the neural network model NNM, an output voltage in the simulation result may be the same as or similar to an output voltage of the reference. In addition, as a result of the computing system 100 performing a ring oscillator simulation by using the neural network model NNM, a current in the simulation result may be the same as or similar to a current of the reference. By using the semiconductor process and design optimization method according to embodiments, a device model capable of accurately predicting a characteristic of a semiconductor device may be provided.

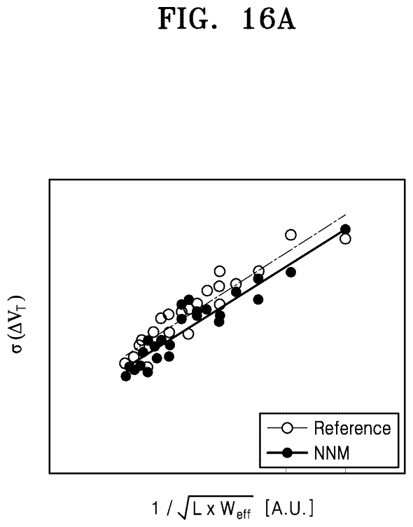

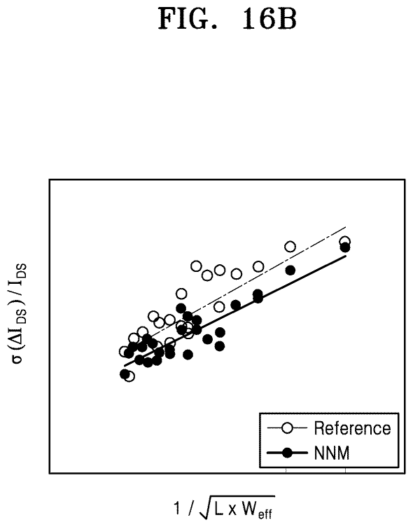

FIGS. 16A and 16B are graphs illustrating results of applying a method of generating a neural network model and performing a circuit simulation by using the neural network model, according to some implementations.

A horizontal axis in the graph of FIG. 16A indicates Equation 5, and a vertical axis indicates a standard deviation of a difference in threshold voltage V_{T} (ΔV_{T}) between adjacent devices (e.g., transistors). Here, L indicates a gate length of a device, and W_{eff} indicates an effective gate width of a device. A horizontal axis in the graph of FIG. 16B indicates Equation 5, and a vertical axis indicates a standard deviation of a difference in current (ΔI_{DS}) between adjacent devices (e.g., transistors). In the graphs of FIGS. 16A and 16B, the simulation result is shown in a solid line, and a reference is shown in a dash-single dotted line.

$$1 / \sqrt{L \times {W}_{eff}} \qquad [ Equation 5 ]$$

As shown in FIGS. 16A and 16B, by using the semiconductor process and design optimization method according to embodiments, a device model capable of accurately predicting a characteristic of a semiconductor device may be provided.

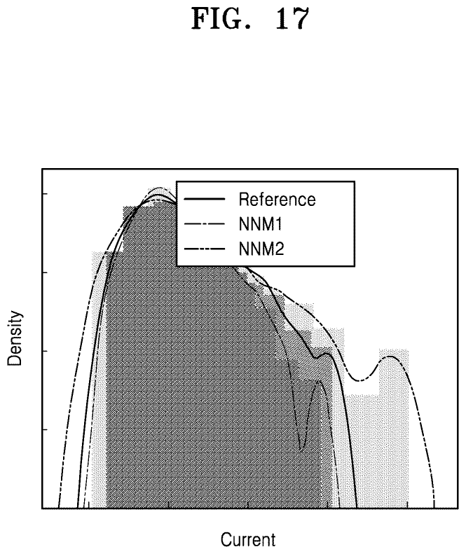

FIG. 17 is a graph illustrating results of applying a method of generating a neural network model and performing a circuit simulation by using the neural network model, according to some implementations.

Referring to FIG. 17, a distribution of radiated current resulting from performing a simulation for a current mirror circuit is shown. A horizontal axis in the graph of FIG. 17 indicates current, and a vertical axis indicates density. In the graph of FIG. 17, a reference is shown in a solid line, a first neural network model NNM1 is shown in a dash-single dotted line, and a second neural network model NNM2 is shown in a dash-double dotted line. The first neural network model NNM1 may be the neural network model NNM according to the embodiment of FIG. 6, and the second neural network model NNM2 may be the neural network model NNM according to the embodiment of FIG. 5. That is, the first neural network model NNM1 may be a model considering a local variance and a global variance, and the second neural network model NNM2 may be a model that does not consider a local variance and a global variance.

As shown in FIG. 17, by using the semiconductor process and design optimization method according to embodiments, a device model capable of accurately predicting a characteristic of a semiconductor device may be provided. In addition, the first neural network model NNM1 may predict a characteristic of a semiconductor device in the same or similar manner as the reference, compared to the second neural network model NNM2.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the simulator has been particularly shown and described with reference to embodiments thereof, it will be understood that various changes in form and details may be made therein without departing from the spirit and scope of the following claims.

What is claimed is:

1. A method of generating a neural network model and performing a circuit simulation by using the neural network model, the method comprising:
generating sample data by performing a process simulation based on a temperature and a process parameter;
training the neural network model based on the sample data;
performing a lightweight operation on the neural network model to generate a lightweight neural network model;
re-training the lightweight neural network model; and
performing the circuit simulation with the process parameter as an input by using the re-trained lightweight neural network model.

2. The method of claim 1, wherein the sample data comprises first simulator output data, second simulator output data, and third simulator output data, and
wherein the first simulator output data comprises current-voltage average data and charge-voltage average data, the second simulator output data comprises current-voltage local variance data and charge-voltage local variance data, and the third simulator output data comprises current-voltage global variance data and charge-voltage global variance data.

3. The method of claim 1, wherein generating the sample data by performing the process simulation based on the temperature and the process parameter comprises:
receiving, by a process simulator, input data comprising at least the temperature and the process parameter;
performing, by the process simulator, the process simulation;
performing, by the process simulator, a device simulation; and
generating, by the process simulator, the sample data comprising at least current-voltage average data and charge-voltage average data.

4. The method of claim 1, wherein generating the sample data by performing the process simulation based on the temperature and the process parameter comprises:
receiving, by a process simulator, input data comprising at least the temperature and the process parameter;
performing, by the process simulator, the process simulation;
performing, by the process simulator, a device simulation for a random dopant fluctuation and a random geometry fluctuation, based on a doping profile; and
generating, by the process simulator, the sample data comprising at least current-voltage local variance data and charge-voltage local variance data.

5. The method of claim 1, wherein generating the sample data by performing the process simulation based on the temperature and the process parameter comprises:
receiving, by a process simulator, input data comprising at least the temperature, the process parameter and also reflecting a process variation;
performing, by the process simulator, the process simulation;
performing, by the process simulator, a device simulation; and
generating, by the process simulator, the sample data comprising at least current-voltage global variance data and charge-voltage global variance data.

6. The method of claim 1, wherein the neural network model is configured to receive a voltage and the process parameter as input data and output a current value and a charge value as output data.

7. The method of claim 6, wherein the neural network model comprises an input layer, one or more hidden layers, an output layer, and a conversion function unit, and
wherein the conversion function unit is configured to:
convert a first output value corresponding to the current value received from the output layer, based on a first equation, I=I₀·V·sinh(y), wherein I₀ indicates a first normalization factor, Vindicates a voltage between a source and a drain, and y indicates the first output value;
output the first converted output value as a first output data;
convert a second output value corresponding to the charge value received from the output layer, based on a second equation, Q=Q₀·x, wherein Q₀ indicates a second normalization factor, and x indicates the second output value; and
output the second converted output value as a second output data.

8. The method of claim 1, wherein the neural network model is configured to receive a voltage and the process parameter as input data and output a first output parameter and a second output parameter as output data, and
wherein the first output parameter comprises at least one of current average data, current local variance data, charge average data, and charge local variance data, and
the second output parameter comprises at least one of current average data, current global variance data, charge average data, and charge global variance data.

9. The method of claim 1, wherein training the neural network model based on the sample data comprises:
generating output data comprising a first output parameter and a second output parameter;
calculating a value of a loss function based on the output data and target data in the sample data; and
updating the neural network model to reduce the value of the loss function.

10. The method of claim 9, wherein the loss function is defined by an equation:
$$Loss = {D}_{KL} ( N ( {μ}_{{P}_{G}} , {σ}_{{P}_{G}}^{2} ) , N ( {μ}_{{T}_{G}} , {σ}_{{T}_{G}}^{2} ) ) + {D}_{KL} ( N ( {μ}_{{P}_{L}} , {σ}_{{P}_{L}}^{2} ) , N ( {μ}_{{T}_{L}} , {σ}_{{T}_{L}}^{2} ) )$$
wherein, Loss indicates the loss function, D_{KL} indicates a Kullback-Leibler divergence, N indicates a normal distribution, μ_{P}_{_{G}} indicates average data in the second output parameter, σ_{P}_{_{G}}² indicates global variance data in the second output parameter, μ_{T}_{_{G}} indicates average data in the target data, σ_{T}_{_{G}}² indicates global variance data in the target data, μ_{P}_{_{L}} indicates average data in the first output parameter, σ_{P}_{_{L}}² indicates local variance data in the first output parameter, μ_{T}_{_{L}} indicates average data in the target data, and σ_{T}_{_{L}}² indicates local variance data in the target data.

11. The method of claim 1, wherein training the neural network model based on the sample data comprises training the neural network model based on all weights,
performing the lightweight operation on the neural network model comprises:
splitting the weights into a first weight group and a second weight group; and
initializing weights of the first weight group,
re-training the lightweight neural network model comprises re-training the neural network model based on weights included in the second weight group, and
a number of weights included in the first weight group is half a number of all weights.

12. The method of claim 1, further comprising:
dividing the sample data into training data used in the training of the neural network model and validation data used in the re-training of the lightweight neural network model;
determining whether a fit between target data and output data of the neural network model is accurate;
adjusting a parameter of the neural network model until a threshold fit between the target data and the output data is reached;
after the re-training of the lightweight neural network model, converting the lightweight neural network model into a format corresponding to a circuit simulator; and
determining whether characteristics of a circuit resulting from the circuit simulation satisfy requirements.

13. The method of claim 1, further comprising performing a calibration operation based on output data of the neural network model and measurement data in the sample data.

14. A computing device comprising at least one processor and a memory,
wherein the memory stores instructions that, when executed by the at least one processor, allow the at least one processor to generate a neural network model and perform a circuit simulation by using the neural network model, and
the at least one processor is configured to:
generate sample data by performing a process simulation based on a temperature and a process parameter;
train the neural network model based on the sample data;
perform a lightweight operation on the neural network model to generate a lightweight neural network model;
re-train a lightweight neural network model; and
perform the circuit simulation with the process parameter as an input by using the re-trained lightweight neural network model.

15. The computing device of claim 14, wherein the sample data comprises first simulator output data, second simulator output data, and third simulator output data, and
wherein the first simulator output data comprises current-voltage average data and charge-voltage average data, the second simulator output data comprises current-voltage local variance data and charge-voltage local variance data, and the third simulator output data comprises current-voltage global variance data and charge-voltage global variance data.

16. The computing device of claim 14, wherein the neural network model comprises:
an input layer configured to receive a voltage and the process parameter as input data;
one or more hidden layers;
an output layer; and
a conversion function unit configured to convert an output value received from the output layer and output a current value and a charge value as output data.

17. The computing device of claim 14, wherein the neural network model comprises:
an input layer configured to receive a voltage and the process parameter as input data;
one or more hidden layers;
an output layer; and
a conversion function unit configured to convert an output value received from the output layer and output a first output parameter and a second output parameter as output data, and
wherein the first output parameter comprises at least one of current average data, current local variance data, charge average data, and charge local variance data, and
the second output parameter comprises at least one of current average data, current global variance data, charge average data, and charge global variance data.

18. The computing device of claim 14, wherein the training of the neural network model based on the sample data comprises:
generating output data;
calculating a value of a loss function based on the output data and target data in the sample data; and
training the neural network model to reduce the calculated value of the loss function.

19. The computing device of claim 14, wherein training the neural network model based on the sample data comprises training the neural network model based on all weights,
performing the lightweight operation on the neural network model to generate the lightweight neural network model comprises:
splitting the weights into a first weight group and a second weight group; and
initializing weights of the first weight group,
re-training the lightweight neural network model comprises re-training the lightweight neural network model based on weights included in the second weight group, and
a number of weights included in the first weight group is half a number of all weights.

20. A method of generating a neural network model and performing a circuit simulation by using the neural network model, the method comprising:
generating sample data by performing a process simulation based on a temperature and a process parameter;
dividing the sample data into training data and validation data;
training the neural network model based on the training data;
determining whether a fit between target data and output data of the neural network model is accurate;
adjusting a parameter of the neural network model until a threshold fit between the target data and the output data is reached;
performing a lightweight operation on the neural network model to generate a lightweight neural network model;
re-training the lightweight neural network model based on the validation data;
converting the lightweight neural network model into a format corresponding to a circuit simulator; and
performing the circuit simulation with the process parameter as an input by using the converted lightweight neural network model
